(19) United States
(12) Patent Application Publication
(10) Pub. No.: US 2024/0145798 A1
(43) Pub. Date: May 2, 2024

(54) DISTRIBUTED BATTERY MANAGEMENT SYSTEM AND BATTERY RECORD DEVICE THEREOF

(71) Applicant: Grace Connection Microelectronics Limited, Zhubei City (TW)

(72) Inventor: Pei Wei Chen, Taipei (TW)

(73) Assignee: Grace Connection Microelectronics Limited, Zhubei City (TW)

(21) Appl. No.: 18/141,970

(22) Filed: May 1, 2023

(30) Foreign Application Priority Data
Oct. 31, 2022 (TW) 111141319

(51) Int. Cl. H01M 10/48; G01R 31/36; G01R 31/371; H01M 10/42; H01M 10/44

(52) U.S. Cl. CPC H01M 10/482; G01R 31/3648; G01R 31/371; H01M 10/4257; H01M 10/441; H01M 2010/4271; H01M 2010/4278

(57) ABSTRACT

A distributed battery management system, for managing a plurality of battery management units, wherein each of the battery management units, includes: a first battery cell, forming a charge-discharge connection at least with a second battery cell in a second battery management unit; a monitor circuit, monitoring a discharge process of the first battery cell via the charge-discharge connection, to record a discharge voltage time history of the first battery cell; and a calculation unit, calculating a real-time maximal energy storage capacity of the first battery cell, by an electrochemical equation calculated based on the discharge voltage time history and an electrical current time history of the first battery cell during the discharge process. The history of the real-time maximal energy storage capacity of the battery cell may be stored as an identity resume of the battery cell, in a battery resume record device.

### CROSS REFERENCE

The present invention claims priority to TW 111141319 filed on Oct. 31, 2022.

### BACKGROUND OF THE INVENTION

### Field of Invention

The present invention relates to a distributed battery management system, especially relates to a distributed battery management system and battery record device thereof, which determines a real-time and online maximal energy storage capacity of a battery cell based on an equation calculated by a voltage, a current and time online in the discharging process of the battery cell.

### Description of Related Art

In the trend of more and more demands based on eco-requirement and power saving, it is very important to manage a charge/discharge efficiency of the battery cell. The current storage devices are usually equipped with multiple battery cells, wherein the charging/discharging status of each battery cell may include performance deviation since ex-factory. This deviation between the battery cells may increase over a long period of working time, which may cause damage or malfunction in a portion of the battery cells. For example, the damage may result in a poor performance of all of the battery cells even when few of the battery cells in series connection does not supply electricity, or few of the battery cells in parallel connection can not to be fully charged by consuming a large amount of electricity. In the past, when some of the battery cells inside were damaged, the whole power storage device was often recycled or discarded (even when some of the battery cells therein may still be in a good performance). The prior technique cannot sense the real-time maximal energy storage capacities of individual battery cells; that is, it is not possible to online determine the performance or health of each of the battery cells one-on-one. In the prior art, the Coulomb discharge meter can be used to determine the maximal energy storage capacity of a battery cell by fully discharging the battery cell. However, the full discharge can cause partial damage or degradation in the battery cell, which makes it difficult to measure an accurate value by the Coulomb discharge meter. Further, the full discharge takes a long process time, the determined result is no longer accurate. Another approach is fast discharging, which has a shorter process with high noise and a high discharge current in the discharging process, so that a high proportion of electrical energy is converted into heat, so that the sensing result of maximal energy storage capacity is lower than real one.

In view of the above, it important to determine the accurate real-time maximal energy storage capacity for managing the battery performance of the battery cells in an energy storage device. In particular, a real-time monitor capability of the present invention, can accurately determine the status of each of the battery cells to avoid unnecessary wastage caused by the failure by few battery cells inside the device, or to avoid a misjudgment of the battery cells status to cause a battery burst.

In addition, the qualities of batteries required in electronic devices, are greatly diverse from the computing devices to the emergency lighting. Therefore, the quality of batteries must be managed precisely based on different battery requirements, to avoid unnecessary wastage. Besides, the current battery resumes according to the determined values, can be easily falsified, to be not credible nor verifiable, which also needs a trustworthy technology to improve these drawbacks.

### SUMMARY OF THE INVENTION

In view of the above, the present invention provides a distributed battery management system, for on-line managing a plurality of battery management units by on-line determining the real-time maximal energy storage capacity. Therein, each of the battery management units, includes: a first battery cell, forming a charge-discharge connection at least with a second battery cell in a second battery management unit; a monitor circuit, monitoring a discharge process of the first battery cell via the charge-discharge connection, to record a discharge voltage time history of the first battery cell; and a calculation unit, calculating a real-time maximal energy storage capacity of the first battery cell, by an electrochemical equation calculated based on the discharge voltage time history and an electrical current time history of the first battery cell during the discharge process.

In one embodiment, the calculation unit is in a one-to-one disposition in the battery management unit; or, the calculation unit is disposed in the distributed battery management system to have a one-to-many connection with the battery management units.

In one embodiment, the distributed battery management system further includes a signal communication unit to provide a signal connection between the battery management units. The signal communication unit can be disposed near the battery management unit; for example, the signal communication unit is in a one-to-one disposition in one of the battery management units. Or, the signal communication unit is disposed in the distributed battery management system to have a one-to-many connection with the battery management units.

In one embodiment, the electrical current time history may be obtained by sensing a discharge current of the first battery cell, sensing a discharge current in the charge-discharge connection, or by conversion from the voltage time history.

In one embodiment, the groundings of the battery management units in the charge-discharge connection, are insulated from each other.

In one embodiment, the distributed battery management system, further includes a master control unit, which controls the charge and discharge of the battery management units through the signal connection.

In one embodiment, the signal connection includes a wired signal connection (for example, a wired daisy chain), or a wireless signal connection.

In one perspective of the present invention, the history of the real-time maximal energy storage capacity of the battery cell can be stored in a battery resume record device, as an identity resume of the battery cell. In one embodiment, the battery resume record device of the present invention, includes: a battery management unit and a memory unit (or, a calculation unit and a memory unit). The memory unit, stores a history record of the real-time maximal energy storage capacity of the battery cell. In one embodiment, the battery resume record device further includes a comparison unit, for comparing the history record of the real-time maximal energy storage capacity, with the real-time maximal energy storage capacity of the battery cell calculated by a calculation unit, to determine whether the history record corresponds to the battery cell.

In one perspective, the present invention provides a distributed battery management system, which includes a plurality of battery management units. Therein, a first battery management unit includes: a first battery cell, forming a charge-discharge connection at least with a second battery cell in a second battery management unit. The distributed battery management system further includes a monitor circuit, which monitors a discharge process of the first battery cell via the charge-discharge connection, to record a discharge voltage time history of the first battery cell as an identity resume of the first battery cell. The battery resume record device, further includes: a closed-form solution processor, calculating a real-time maximal energy storage capacity of the first battery cell, by calculating a closed form solution of an electrochemical equation corresponding to a charge/discharge characteristic of the first battery cell, based on the discharge voltage time history and an electrical current time history of the first battery cell. The battery resume record device, yet further includes: a signal communication unit, which provides a signal connection between the battery management units to form a signal connection.

In one embodiment, the closed-form solution processor is in a one-to-one disposition in each of the battery management units; or, the closed-form solution processor is disposed in the distributed battery management system to have a one-to-many connection with the battery management units.

The objectives, technical details, features, and effects of the present invention will be better understood with regard to the detailed description of the embodiments below, with reference to the attached drawings.

### BRIEF DESCRIPTION OF THE DRAWINGS

FIG. 1 shows a schematic diagram of a distributed battery management system according to one embodiment of the present invention.

FIG. 2 shows a schematic diagram of the discharge characteristics of a battery cell according to one embodiment of the present invention.

FIGS. 3 and 4 show a schematic diagram of a distributed battery management system according to two embodiments of the present invention.

FIG. 5 shows a schematic diagram of a battery management unit according to one embodiment of the present invention.

FIGS. 6 and 7 show two schematic diagrams of the distributed battery management systems according to another two embodiments of the present invention.

FIG. 8 shows one schematic diagram of a battery resume record device according to an embodiment of the present invention.

### DESCRIPTION OF THE PREFERRED EMBODIMENTS

The drawings as referred to throughout the description of the present invention are for illustration only, to show the interrelations between the circuits and the signal waveforms, but not drawn according to actual scale of circuit sizes and signal amplitudes and frequencies.

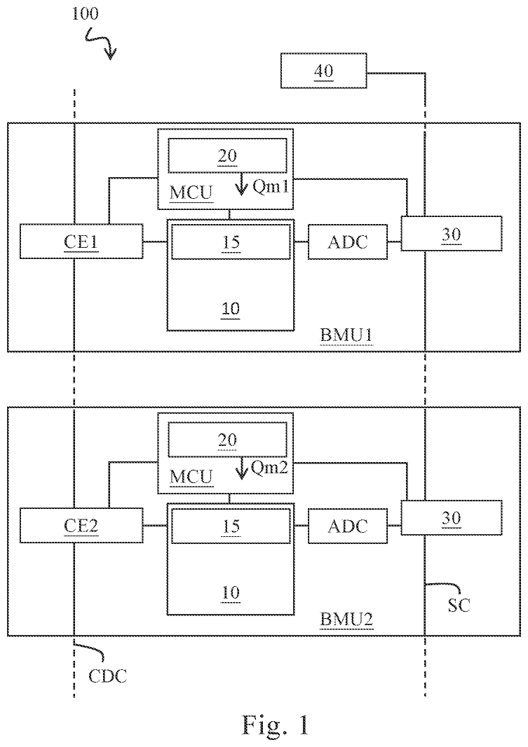

Referring to FIG. 1, in view of the aforementioned technical needs, the present invention provides a distributed battery management system 100 for managing a plurality of battery management units (illustrated by two battery management units BMU1 and BMU2 as an exemplar number of the battery management units, and the distributed battery management system can include other numbers of the battery management units in other embodiments). Each battery management unit (for example, battery management unit BMU1) includes: a first battery cell CE1, the first battery cell CE1 and at least a second battery cell CE2 in a second battery management unit BMU2 forming a charge-discharge connection CDC; a monitor circuit 10, monitoring a discharge voltage time history of the first battery cell CE1 (or the second battery cell CE2) during the discharging process; and a calculation unit 20 (in this embodiment, the calculation unit 20 is disposed in a micro control unit MCU. In one embodiment, the calculation unit 20 can be disposed outside the micro control unit MCU), calculating a real-time and on-line maximal energy storage capacity Qm1 of the first battery cell CE1 (or calculating a real-time and on-line maximal energy storage capacity Qm2 of the second battery cell CE2, etc.), by an electrochemical equation (explained in later embodiments) calculated based on the discharge voltage time history and an electrical current time history of the first battery cell CE1 during the discharge process. The first and second battery cells CE1, CE2 are respectively disposed in the battery management units EMU1, BMU2. The battery cells CE1 and CE2 are electrically connected in series and form a charge-discharge connection CDC. Each of the battery cells has a limited energy storage capacity, while the charge-discharge connection CDC includes a number of battery cells CE1 and CE2, to greatly increase the discharge voltage (e.g. in series connection) or a discharge current (e.g. in parallel connection) of the distributed battery management system 100. Regardless of whether the battery cells are connected in series, in parallel or in series-parallel, the overall charge/discharge capability of the interconnected battery management units can be substantially increased in these connections. In addition, the aforementioned maximal energy storage capacity can be a real-time and on-line maximal energy storage capacity, to correspond to the real-time maximal energy storage capacity of each battery cells. This real-time and on-line maximal energy storage capacity can be calculated or determined without the full discharge in the prior art, nor comparison with a nominal storage capacity (e.g., factory-rated storage data). The electrochemical equation in this invention is based on the real-time and on line discharge of electricity of the battery cell, and it can achieve a theoretical electrochemical solution. Besides, the distributed battery management system in this embodiment, is based on the example of the battery management unit BMU1 (or the battery management units BMU1 and BMU2). In one embodiment, other battery management unit numbers in the distributed battery management system can be implemented based on the technology of the present invention, without limit on the number of battery management units shown in the figures.

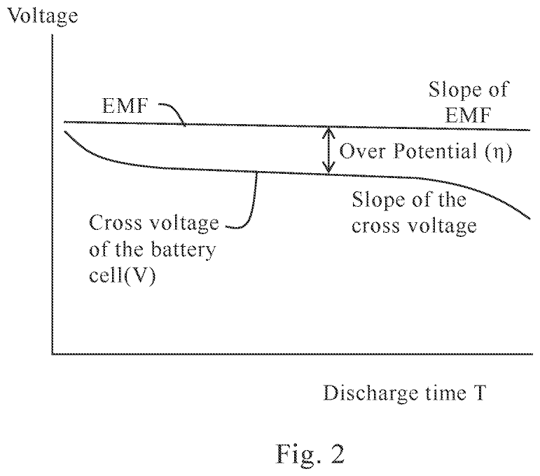

Please refer to FIG. 2, wherein the battery cell's electromotive force (EMF) can be determined by current discharge or open circuit voltage (OCV). When the battery cell is in a stage of discharge (e.g. 200 to 4000 seconds, or other discharge stages), an over potential η of the battery cell is related to an electrode resistance Re, the resistance between the electrode to an electrolyte Rct, the real-time maximal energy storage capacity Qm, and the discharge current I. A simplified relationship is η(t)=I×(Re+Rct+k×Qm/(Qm−I×T)+Zw), wherein k is a reaction rate coefficient of a conversion reaction efficiency between the electrode and the electrolyte, and Zw is the Warburg impedance. The electrochemical equation applied in this invention can be derived into various forms of the aforementioned relationship. For example, it is possible to generate a discharge characteristic equation based on the discharge voltage time history, the electrical current time history and the real-time maximal energy storage capacity of the electrochemical reaction in the battery cell. In addition, when the temperature of the battery cell changes significantly, the Qm of the electrochemical equation can be also affected thereby. In this way, the invention can generate a closed form solution for the real-time maximal energy storage capacity Qm by means of an on-line calculation or other real time calculation operations.

According to this invention, the battery cell's real-time maximal energy storage capacity Qm can be determined, and the battery cell's state of health (SOH), state of charge (SOC), or end of life can be accordingly determined.

In one embodiment, the monitor circuit 10 in the battery management unit EMU1, monitors the discharge voltage time history of the battery cell CE1 in the discharging process. The monitor circuit 10 can generate the discharge voltage time history based on the results by the voltage sensing unit 15 in the battery cell CE1, at any time during the discharge process.

In one embodiment, the real-time maximal energy storage capacities Qm1 and Qm2 of the battery cells CE1 and CE2 generated by the present invention, can be used to compare the battery management units BMU1 and BMU2 respectively. The battery management units BMU1 and BMU2 can be compared based on the decrease rate of the real-time maximal energy storage capacity at different times during the discharging process, to determine whether the battery cells are normal or not. For example, if the voltage decrease is too fast, the battery or related circuitry may be unfunctional.

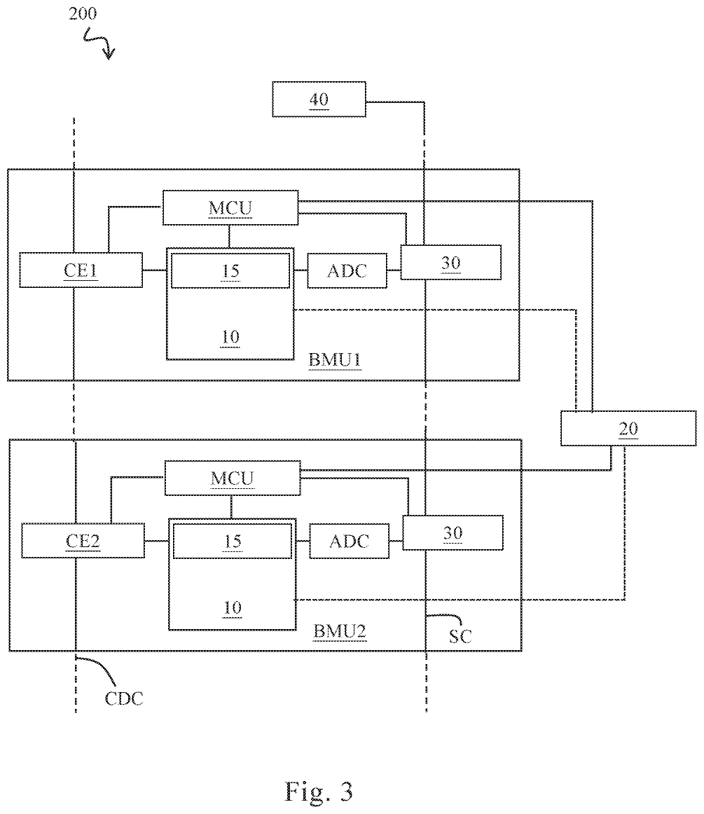

In the embodiment of FIG. 1, the calculation units 20 can be in a one-to-one disposition in the battery management units BMU1 and BMU2. Cr, in the embodiment of FIG. 3, the calculation units 20 is disposed in the distributed battery management system 200 to have a one-to-many connection with the battery management units BMU1, BMU2. In particular, the calculation unit 20 can be disposed at the near or in a remote device (or cloud device). In short, the disposition of the calculation unit 20 can depend on need or cost.

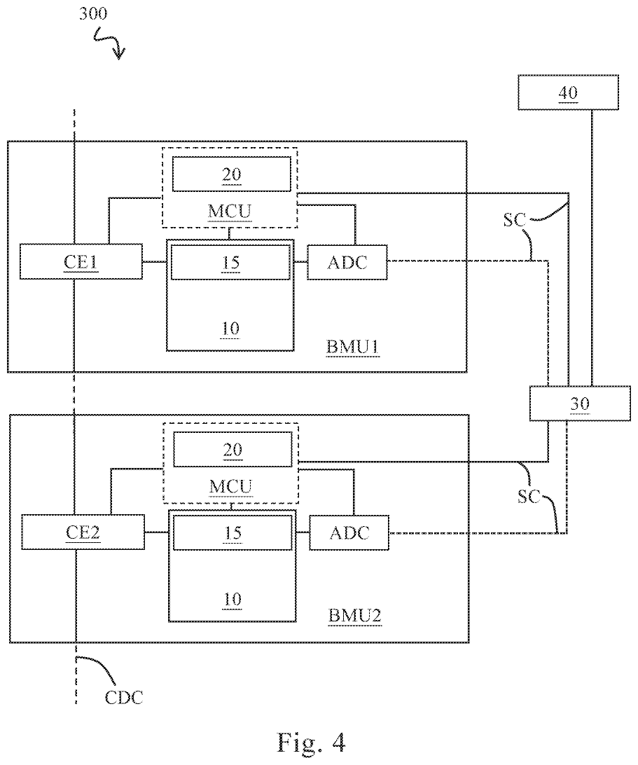

Referring to the embodiments in FIGS. 1, 3 and 4, each of the distributed battery management system 100, 200 and 300, includes a signal communication unit. 30 (or at least one signal communication unit 30), which includes a signal connection SC (e.g. a wired signal connection or a wireless signal connection) between the battery management unit BMU1 and at least another battery management unit BMU2. The signal communication units 30 can be disposed at the near, for example, in the battery management units BMU1 and BMU2 (FIGS. 1 and 3). Or, the calculation unit 30 is disposed in the distributed battery management system 300 (FIG. 4), to have a one-to-many connection with the battery management units BMU1 and BMU2. Alternatively, when the battery management units BMU1 and BMU2 can be controlled from the cloud, the signal communication unit 30 can also be disposed in a cloud device to connect the distributed battery management system 300 with remote control signals.

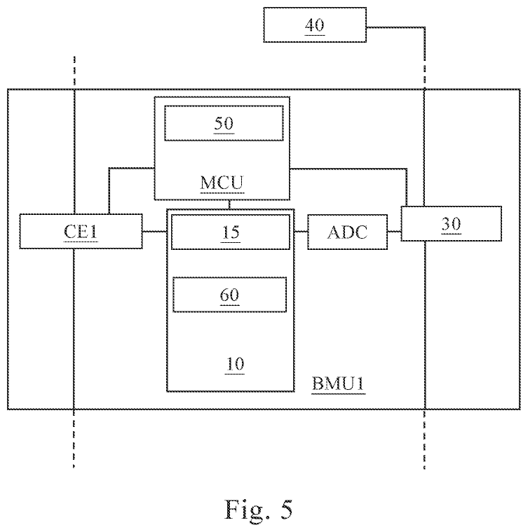

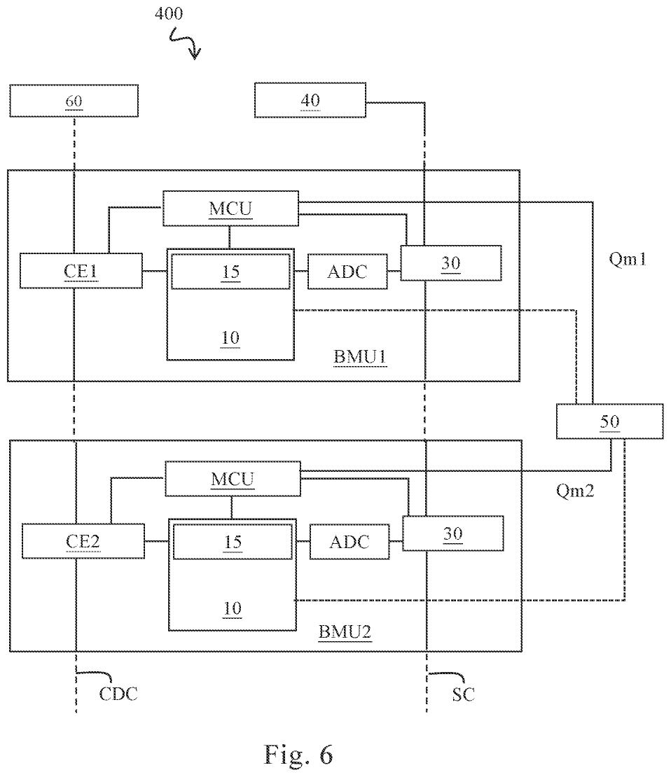

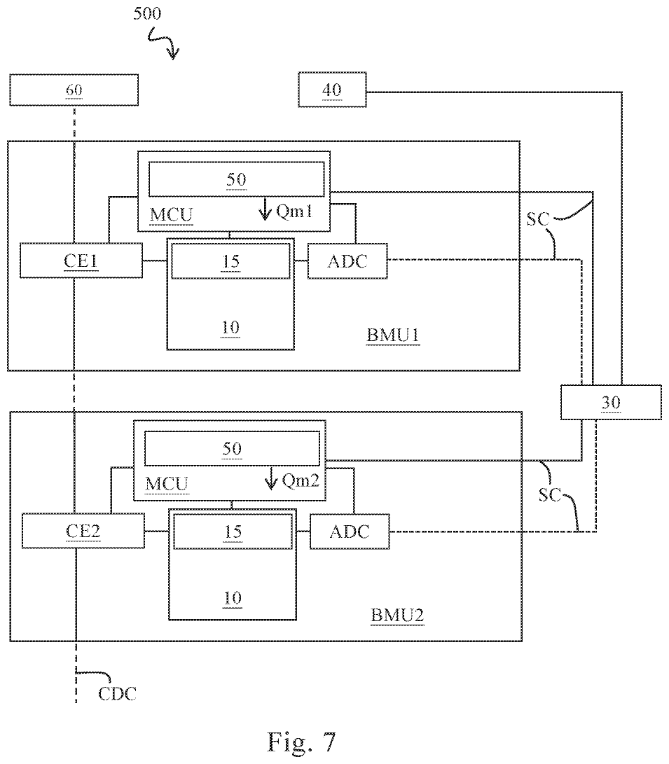

In one embodiment, the electrical current time history is generated by sensing the discharge current through the first battery cell CE1 (in FIG. 5, the monitor circuit 10 further includes an electrical current sensing unit 60 to sense the discharge current of the first battery cell CE1, for generate the electrical time history). Or, each of the distributed battery management systems 400, 500 (FIGS. 6 and 7), includes a current sensing unit 60 outside the battery management units BMU1 and BMU2, wherein the current sensing unit 60 is connected to the charge-discharge connection CDC in a series connection, to sense the discharge current through the first battery cell CE1 to generate the current time history). Or, the discharge current in the charge-discharge connection CDC, can be obtained by converting the discharge voltage time history; for example, sensing the current across the first battery cell CE1 by means of a voltage divider circuit).

In one embodiment, the groundings of the battery management units BMU1 and BMU2 connected by the charge-discharge connection CDC, are insulated from each other.

In one embodiment, the signal connection SC includes a wired signal connection or a wireless signal connection. In one embodiment, the signal communication unit 30 may include a capacitive sensing circuit or a magnetic field sensing circuit, for transmitting a wired signal connection by means of electric or magnetic field induction. Regarding the wired signal connection, the signal communication unit 30 including the capacitive sensing circuit or the magnetic field sensing circuit, can be not influenced by grounding level difference between the battery management units BMU1 and BMU2. The signal communication unit 30 can be connected to a wired signal connection by means of a no-contact transmission method such as electric or magnetic field induction, which is not influenced by grounding level difference between the battery management units BMU1 and BMU2. Alternatively, the signal communication unit 30 has a wireless signal receiving and transmitting function, to create a wireless signal connection for receiving and transmitting wireless signals. In FIGS. 1, 3, 4, 5, 6 and 7, the signal communication units illustrated therein are connected by the wired signal connection, wherein if necessary, the wired signal connection can be converted into to the wireless signal connection.

Please refer to the embodiments shown in FIGS. 1, 3, 4, 6 and 7, wherein each of the distributed battery management systems 100, 200, 300, 400 and 500, includes a master control unit 40. The master control unit 40 transmits signals through the signal connection SC (or, through the signal communication unit 30 and the signal connection SC) to control the charge/discharge of the battery management units BMU1 and BMU2.

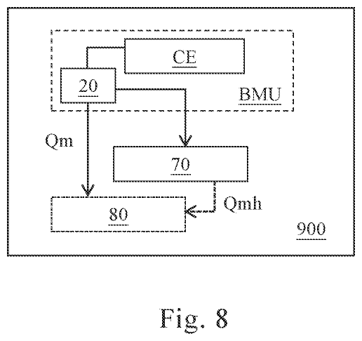

As aforementioned, the quality management of batteries is critical, especially the management in terms of the real-time maximal energy storage capacity. However, the prior battery history technique can be easily falsified, for example by relabeling a good quality record onto a poor quality battery. Therefore, it needed to have an easily verifiable and credible battery history technique away from these cheating tricks. With reference to FIG. 8, according to one perspective of the present invention, a battery resume record device 900 is provided. The battery resume record device 900 includes: a calculation unit 20 (e.g. the calculation unit 20 in the battery management unit BMU of the preceding embodiment, or the calculation unit 20 outside the battery management unit EMU), and a memory unit 70. The memory unit 70 stores the real-time maximal energy storage capacity Qm calculated by each of the calculation units 20 (if required, the value for comparison between the memory unit and the comparison unit, can be not limited to the real-time maximal energy storage capacity Qm. For example, the comparison of the history records of state of health (SOH), state of charge (SOC), or end of life). The detail of the battery management unit BMU can be referred to other embodiments of the invention, which is not repeated in detail herein.

With reference to FIG. 8, in one embodiment, the battery resume record device 900 includes a comparison unit 80 for comparing the history record Qmh of real-time maximal energy storage capacity, with the battery cell's Qm calculated by the calculation unit, to determine whether the history record Qmh corresponds to the battery cell CE. For example, whether the difference between the history record Qmh and the calculated real-time maximal energy storage capacity Qm is too large, could mean that the battery cell CE cannot correspond to the history record Qmh of the real-time maximal energy storage capacity and have been replaced. In one embodiment, the history record can be not limited to the real-time maximal energy storage capacity; for example, the history record may further include the state of health (SOH), the state of charge (SOC), or the end of life of the battery cell CE. All of these history records can further be used as an identity resume for determining the correspondence to the battery cell CE.

In the preceding embodiments, the real-time maximal energy storage capacity of the battery cell CE can be obtained by calculating the closed form solution of the equation based on the voltage and the current of the battery cell CE during the discharging process. The maximal energy storage capacity Qm (or other history record Qmh) is obtained from the closed form solution of the electrochemical equation, the battery cell CE is in a one-to-one correlation with the battery cell CE. Alternatively, the memory units 70 and the comparison unit 80 may be disposed in the same assembly, in a one-to-one disposition in the battery cell CE. Alternatively, one of the memory unit 70 and the comparison unit 80, is in a one-to-one disposition in the battery cell CE, the other is disposed in the cloud device. Thus, the user can determine the arrangement of how to dispose the components according to his needs.

With further reference to FIGS. 5, 6 and 7, according to one perspective of the present invention, each of the distributed battery management systems 400, 500, can be used for managing a plurality of battery management units BMU1 and BMU2. The battery management unit BMU1 includes: a first battery cell CE1, the first battery cell CE1 and at least one second battery cell CE2 in a second battery management unit BMU2 forming a charge-discharge connection CDC between the first battery cell CE1 and the second battery cell CE2; and a monitor circuit 10, monitoring a discharge voltage time history of the first battery cell CE1 during the discharge process. Besides, each of the distributed battery management systems 400 and 500, further includes: a closed-form solution processor 50, calculating a real-time maximal energy storage capacity Qm1 of the first battery cell CE1, by calculating a closed form solution of an electrochemical equation corresponding to a charge/discharge characteristic of the first battery cell CE1, based on the discharge voltage time history and the electrical current time history of the first battery cell CE1; and a signal communication unit 30, providing a signal connection. SC between the battery management unit BMU1 and the second battery management unit BMU2.

In one embodiment, the closed-form solution processor 50 can be disposed at the near. For example, the closed-form solution processors 50 are in a one-to-one in the battery management units BMU1 and BMU2 (FIG. 7). Or, the closed-form solution processor 50 is disposed in the distributed battery management system 400 (FIG. 6), to have a one-to-many connection with the battery management units BMU1 and BMU2. If needed, the closed-form solution processor 50 can be disposed remotely; for example, the calculation of closed solutions is operated from the cloud.

The present invention has been described in considerable detail with reference to certain preferred embodiments thereof. It should be understood that the description is for illustrative purpose, not for limiting the scope of the present invention. An embodiment or a claim of the present invention does not need to achieve all the objectives or advantages of the present invention. The title and abstract are provided for assisting searches but not for limiting the scope of the present invention. Those skilled in this art can readily conceive variations and modifications within the spirit of the present invention. It is not limited for each of the embodiments described hereinbefore to be used alone; under the spirit of the present invention, two or more of the embodiments described hereinbefore can be used in combination. For example, two or more of the embodiments can be used together, or, a part of one embodiment can be used to replace a corresponding part of another embodiment. In view of the foregoing, the spirit of the present invention should cover all such and other modifications and variations, which should be interpreted to fall within the scope of the following claims and their equivalents.

What is claimed is:

1. A distributed battery management system, for managing a plurality of battery management units, each of the battery management units including:
a first battery cell, forming an electrical connection at least with a second battery cell in a second battery management unit;
a monitor circuit, monitoring a discharge process of the first battery cell via the electrical connection, to record a discharge voltage time history of the first battery cell; and
a calculation unit, calculating a real-time maximal energy storage capacity of the first battery cell, by an electrochemical equation calculated based on the discharge voltage time history and an electrical current time history of the first battery cell during the discharge process.

2. The distributed battery management system according to claim 1, wherein the calculation unit is in a one-to-one disposition in the battery management unit; or, the calculation unit is disposed in the distributed battery management system, to have a one-to-many connection with the battery management units.

3. The distributed battery management system according to claim 1, further including a signal communication unit, providing a signal connection between the battery management units, wherein the signal communication unit is in a one-to-one disposition in each of the battery management units, or the signal communication unit is disposed in the distributed battery management system, to have a one-to-many connection with the battery management units.

4. The distributed battery management system according to claim 3, further including a master control unit, controlling charge and discharge of the battery management units through the signal connection.

5. The distributed battery management system according to claim 3, wherein the signal connection includes a wired signal connection or a wireless signal connection.

6. The distributed battery management system according to claim 1, wherein the electrical current time history is obtained by sensing a discharge current of the first battery cell, sensing a discharge current in the charge-discharge connection, or conversion from the voltage time history.

7. The distributed battery management system according to claim 1, wherein the electrochemical equation is a discharge characteristic equation based on the discharge voltage time history, the electrical current time history and the real-time maximal energy storage capacity in the battery cell of the electrochemical reaction.

8. The distributed battery management system according to claim 1, wherein the groundings of the battery management units connected by the charge-discharge connection, are isolated from each other.

9. A battery resume record device, including:
a calculation unit, calculating a real-time maximal energy storage capacity of the first battery cell; and
a memory unit, storing a history record of the real-time maximal energy storage capacity of the battery cell as an identity resume of the first battery cell;
wherein, the real-time maximal energy storage capacity is a closed form solution of an electrochemical equation calculating a voltage and a current of the battery cell during a discharging process, and the real-time maximal energy storage capacity is in a one-to-one correlation with the battery cell.

10. The battery resume record device according to claim 9, further including: a comparison unit, comparing the history record of the maximal energy storage capacity, with the maximal energy storage capacity of the battery cell, to determine whether the history record corresponds to the battery cell.

11. The battery resume record device according to claim 9, wherein the history record includes state of health (SOH), state of charge (500), or end of life of the battery cell.

12. A distributed battery management system, including:
a plurality of battery management units, wherein a first battery management unit including:
first battery cell, forming a charge-discharge connection at least with a second battery cell in a second battery management unit; and
a monitor circuit, monitoring a discharge process of the first battery cell via the charge-discharge connection, to record a discharge voltage time history of the first battery cell;
a closed-form solution processor, calculating a real-time maximal energy storage capacity of the first battery cell, by calculating a closed form solution of an electrochemical equation corresponding to a charge/discharge characteristic of the first battery cell, based on the discharge voltage time history and an electrical current time history of the first battery cell; and
a signal communication unit, providing a signal connection between the battery management units to form a signal connection.

13. The distributed battery management system according to claim 12, wherein the electrical current time history is obtained by sensing a discharge current of the first battery cell, sensing a discharge current in the charge-discharge connection, or by conversion from the voltage time history.

14. The distributed battery management system according to claim 12, wherein the closed-form solution processor is in a one-to-one disposition in each of the battery management units; or, the closed-form solution processor is disposed in the distributed battery management system to have a one-to-many connection with the battery management units.

15. The distributed battery management system according to claim 12, wherein the signal communication unit is in a one-to-one disposition in each of the battery management units, or the signal communication unit is disposed in the distributed battery management system, to have one-to-many connection with the battery management units.
